(19) United States
(12) Patent Application Publication
(10) Pub. No.: US 2026/0161084 A1
(43) Pub. Date: Jun. 11, 2026

(54) COMPOSITION FOR FORMING RESIST UNDERLAYER FILM CONTAINING ACRYLAMIDE GROUP

(71) Applicant: NISSAN CHEMICAL CORPORATION, Tokyo (JP)

(72) Inventors: Hiroto OGATA, Toyama-shi (JP); Yuki KATO, Toyama-shi (JP); Mamoru TAMURA, Toyama-shi (JP)

(73) Assignee: NISSAN CHEMICAL CORPORATION, Tokyo (JP)

(21) Appl. No.: 18/706,428

(22) PCT Filed: Nov. 9, 2022
(86) PCT No.: PCT/JP2022/041625

§ 371 Date: May 1, 2024

(30) Foreign Application Priority Data
Nov. 10, 2021 (JP) 2021-183351

(51) Int. Cl. G03F 7/11; C08F 220/58; H10P 50/00; H10P 76/20

(52) U.S. Cl. CPC G03F 7/11; C08F 220/58; H10P 50/692; H10P 50/695; H10P 76/2042; H10P 76/2045

(57) ABSTRACT

A composition for forming a resist underlayer film for EB or EUV lithography, the composition containing a polymer and a solvent, wherein the polymer contains a repeating unit represented by the following Formula (1).

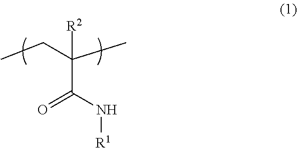

(In Formula (1), R¹ represents a monovalent organic group having 1 to 20 carbon atoms. R² represents a hydrogen atom or an alkyl group having 1 to 6 carbon atoms.)

### TECHNICAL FIELD

The present invention relates to a composition for forming a resist underlayer film for EB or EUV lithography, a resist underlayer film for EB or EUV lithography, a substrate for semiconductor processing, a method for manufacturing a semiconductor element, a pattern forming method, and a method for improving LWR of a resist pattern.

### BACKGROUND ART

In a semiconductor device of LSI (semiconductor integrated circuit) or the like, formation of a fine pattern is required with improvement in integration, and a minimum pattern size in recent years has reached 100 nm or less.

Formation of such a fine pattern in a semiconductor device has been realized by shortening the wavelength of a light source in an exposure device and improving a resist material. At present, an immersion exposure method is used in which exposure is performed through water using argon fluoride (ArF) excimer laser light having a wavelength of 193 nm, which is deep ultraviolet light, as a light source, and various ArF-compatible resist materials based on an acrylic resin have also been developed as resist materials.

Furthermore, as a next-generation exposure technology, an EB exposure method using an electron beam (EB) or an extreme ultraviolet (EUV) exposure method using a soft X-ray having a wavelength of 13.5 nm as a light source has been studied, and the pattern size is 30 nm or less, and further miniaturization has been advanced.

However, along with such miniaturization of the pattern size, rattling of the side walls of the resist pattern (line edge roughness (LER)) and the non-uniformity of the resist pattern width (line width roughness (LWR)) become large, and there is an increasing concern that device performance is adversely affected. Studies have been made to suppress these problems by optimizing an exposure device, a resist material, and process conditions, but sufficient results have not been obtained. Note that the LWR and the LER are related, and the LER is also improved by improving the LWR.

As a method for solving the above problem, there is disclosed a method for improving the LWR and LER by treating a resist pattern using an aqueous solution containing a specific ionic surfactant in a rinsing step after development processing, thereby suppressing defects (defects such as generation of residues and pattern collapse) due to the development processing, and at the same time, dissolving irregularities of the resist pattern (refer to Patent Literature 1).

### CITATION LIST

### Patent Literature

Patent Literature 1: JP 2007-213013 A

### SUMMARY OF INVENTION

### Technical Problem

An object of the present invention is to provide a composition for forming a resist underlayer film for EB or EUV lithography, a resist underlayer film for EB or EUV lithography, a substrate for semiconductor processing, a method for manufacturing a semiconductor element, a pattern forming method, and a method for improving LWR of a resist pattern, which can improve LWR of a resist pattern in EB or EUV lithography.

### Solution to Problem

As a result of intensive studies to solve the above problems, the present inventors have found that the above problems can be solved, and have completed the present invention having the following gist.

That is, the present invention includes the following.
[1] A composition for forming a resist underlayer film for EB or EUV lithography, the composition including:
a polymer; and
a solvent;
wherein the polymer contains a repeating unit represented by the following Formula (1).

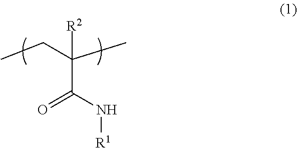

(In Formula (1), R¹ represents a monovalent organic group having 1 to 20 carbon atoms. R² represents a hydrogen atom or an alkyl group having 1 to 6 carbon atoms.)
[2] The composition for forming a resist underlayer film for EB or EUV lithography according to [1], in which R¹ in the Formula (1) represents the following Formula (1X).

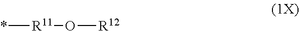

(In Formula (1X), R¹¹ represents an alkylene group having 1 to 4 carbon atoms, and R¹² represents a hydrogen atom, an alkyl group having 1 to 6 carbon atoms, or an alkoxyalkyl group having 2 to 10 carbon atoms in total. * represents an atomic bonding.)
[3] The composition for forming a resist underlayer film for EB or EUV lithography according to [2], in which, in the Formula (1X), R¹¹ represents a methylene group or a 1,2-ethylene group.
[4] The composition for forming a resist underlayer film for EB or EUV lithography according to [2] or [3], in which, in the Formula (1X), R¹² represents a hydrogen atom or an alkoxyalkyl group having 2 to 6 carbon atoms in total.
[5] The composition for forming a resist underlayer film for EB or EUV lithography according to any one of [1] to [4], in which the polymer further contains a repeating unit represented by the following Formula (2).

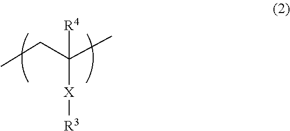

(In Formula (2), X represents a single bond or —COO—, R³ represents a monovalent organic group having 1 to 20 carbon atoms, and R⁴ represents a hydrogen atom or an alkyl group having 1 to 6 carbon atoms. * represents an atomic bonding.)
[6] The composition for forming a resist underlayer film for EB or EUV lithography according to [5], in which X in the Formula (2) represents —COO—, and R³ represents a linear or branched alkyl group having 1 to 20 carbon atoms, a monovalent group having 2 to 20 carbon atoms in total and having a cyclic structure optionally having a heteroatom, or the following Formula (2X).

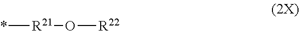

(In Formula (2X), R²¹ represents an alkylene group having 1 to 4 carbon atoms, and R²² represents a hydrogen atom, an alkyl group having 1 to 6 carbon atoms, or an alkoxyalkyl group having 2 to 10 carbon atoms in total.)
[7] The composition for forming a resist underlayer film for EB or EUV lithography according to [6], in which
the linear or branched alkyl group having 1 to 20 carbon atoms is a linear or branched alkyl group having 1 to 6 carbon atoms,
the monovalent group having 2 to 20 carbon atoms in total and having a cyclic structure optionally having a heteroatom is a monovalent group obtained by removing one hydrogen atom from a monocyclic or polycyclic aliphatic ring having 3 to 10 carbon atoms, and
in the Formula (2X), R²¹ represents a methylene group, a 1,2-ethylene group, or a propylene group.
[8] The composition for forming a resist underlayer film for EB or EUV lithography according to [6] or [7], in which
the linear or branched alkyl group having 1 to 20 carbon atoms is a linear or branched alkyl group having 1 to 6 carbon atoms,
the monovalent group having 2 to 20 carbon atoms in total and having a cyclic structure optionally having a heteroatom is a monovalent group obtained by removing one hydrogen atom from a monocyclic or polycyclic aliphatic ring having 3 to 10 carbon atoms, and
in the Formula (2X), R²² represents a hydrogen atom or an alkoxyalkyl group having 2 to 6 carbon atoms in total.
[9] The composition for forming a resist underlayer film for EB or EUV lithography according to any one of [5] to [8], in which a molar ratio between the repeating unit represented by the Formula (1) and the repeating unit represented by the Formula (2) in the polymer (Formula (1):Formula (2)) is 30:70 to 90:10.
[10] The composition for forming a resist underlayer film for EB or EUV lithography according to any one of [1] to [9], further containing a crosslinking agent.
[11] The composition for forming a resist underlayer film for EB or EUV lithography according to any one of [1] to [10], further containing a curing catalyst.
[12] The composition for forming a resist underlayer film for EB or EUV lithography according to any one of [1] to [11], in which the composition is used for forming a resist underlayer film for EB or EUV lithography having a film thickness of 10 nm or less.
[13] A resist underlayer film for EB or EUV lithography which is a cured product of the composition for forming a resist underlayer film for EB or EUV lithography according to any one of [1] to [12].
[14] A substrate for semiconductor processing including:
a semiconductor substrate; and
the resist underlayer film for EB or EUV lithography according to [13].
[15] A method for manufacturing a semiconductor element, the method including:
a step of forming a resist underlayer film on a semiconductor substrate using the composition for forming a resist underlayer film for EB or EUV lithography according to any one of [1] to [12]; and
a step of forming a resist film on the resist underlayer film using a resist for EB or EUV lithography.
[16] A pattern forming method including:
a step of forming a resist underlayer film on a semiconductor substrate using the composition for forming a resist underlayer film for EB or EUV lithography according to any one of [1] to [12];
a step of forming a resist film on the resist underlayer film using a resist for EB or EUV lithography;
a step of irradiating the resist film with EB or EUV, and then developing the resist film to obtain a resist pattern; and
a step of etching the resist underlayer film using the resist pattern as a mask.
[17] A method for improving LWR of a resist pattern, the method including:
a step of forming a resist underlayer film on a semiconductor substrate using the composition for forming a resist underlayer film for EB or EUV lithography according to any one of [1] to [12];
a step of forming a resist film on the resist underlayer film using a resist for EB or EUV lithography; and
a step of irradiating the resist film with EB or EUV, and then developing the resist film to obtain a resist pattern.

### Advantageous Effects of Invention

According to the present invention, it is possible to provide a composition for forming a resist underlayer film for EB or EUV lithography, a resist underlayer film for EB or EUV lithography, a substrate for semiconductor processing, a method for manufacturing a semiconductor element, a pattern forming method, and a method for improving LWR of a resist pattern, which can improve LWR of a resist pattern in EB or EUV lithography.

### DESCRIPTION OF EMBODIMENTS

The present inventors have studied a method capable of improving LWR of a resist pattern in EB or EUV lithography by a method other than the rinsing step.

Then, the present inventors have found that LWR can be improved by providing a resist underlayer film obtained from a composition having a polymer containing a repeating unit represented by the following Formula (1) as a underlayer film of a resist film, and have completed the present invention.

### (Composition for Forming Resist Underlayer Film for EB or EUV Lithography)

The composition for forming a resist underlayer film for EB or EUV lithography (hereinafter may be simply referred to as a “composition for forming a resist underlayer film”) of the present invention contains a polymer and a solvent.

### <Polymer>

The polymer contains a repeating unit represented by the following Formula (1).

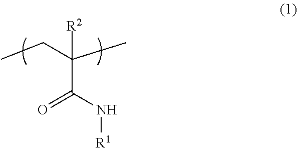

(In Formula (1), R¹ represents a monovalent organic group having 1 to 20 carbon atoms. R² represents a hydrogen atom or an alkyl group having 1 to 6 carbon atoms.)

R¹ in the Formula (1) preferably represents the following Formula (1X).

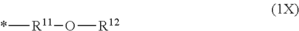

(In Formula (1X), R¹¹ represents an alkylene group having 1 to 4 carbon atoms, and R¹² represents a hydrogen atom, an alkyl group having 1 to 6 carbon atoms, or an alkoxyalkyl group having 2 to 10 carbon atoms in total. * represents an atomic bonding.)

R¹ in the Formula (1) preferably represents an alkyl group having 1 to 6 carbon atoms, a hydroxyalkyl group having 1 to 6 carbon atoms, or a group represented by the following Formula (Ar1).

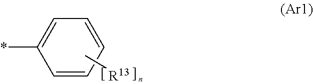

(In Formula (Ar1), R¹³ represents a halogen atom or an alkyl group having 1 to 6 carbon atoms which may be substituted with a halogen atom. n represents an integer of 0 to 5. When there are two or more R¹³, two or more R¹³ may be the same or different. * represents an atomic bonding.)

R² in the Formula (1) is preferably a hydrogen atom or a methyl group.

The alkylene group having 1 to 4 carbon atoms in the present invention may be any of a linear form, a branched form, and a cyclic form. Examples of the alkylene group having 1 to 4 carbon atoms include an alkylene group having 1 to 3 carbon atoms.

Examples of the alkylene group having 1 to 4 carbon atoms include a methylene group, a 1,2-ethylene group, a 1,1-ethylene group, a 1,2-propylene group, a 1,3-propylene group, a tetramethylene group, a 1-methyl-1,3-propylene group, a 2-methyl-1,3-propylene group, and a 2-methyl-1,2-propylene group.

The alkyl group having 1 to 6 carbon atoms in the present invention may be linear, branched, or cyclic. Examples of the alkyl group having 1 to 6 carbon atoms include an alkyl group having 1 to 4 carbon atoms.

Examples of the alkyl group having 1 to 6 carbon atoms include a methyl group, an ethyl group, an n-propyl group, an iso-propyl group, a cyclopropyl group, an n-butyl group, an iso-butyl group, a sec-butyl group, a tert-butyl group, a cyclobutyl group, a 1-methyl-cyclopropyl group, a 2-methyl-cyclopropyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, an n-hexyl group, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, a 1-ethyl-2-methyl-n-propyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group.

Examples of the alkoxyalkyl group having 2 to 10 carbon atoms in total in the present invention include alkoxyalkyl groups having 2 to 6 carbon atoms in total.

Examples of the alkoxyalkyl group having 2 to 10 carbon atoms in total include a methoxymethyl group, a 1-methoxyethyl group, a 2-methoxyethyl group, a 1-methoxypropyl group, a 2-methoxypropyl group, a 3-methoxypropyl group, a 1-methoxy-1-methylethyl group, a 2-methoxy-1-methylethyl group, an ethoxymethyl group, a 1-ethoxyethyl group, a 2-ethoxyethyl group, a 1-ethoxypropyl group, a 2-ethoxypropyl group, a 3-ethoxypropyl group, a 1-ethoxy-1-methylethyl group, a 2-ethoxy-1-methylethyl group, a propoxymethyl group, a 1-propoxyethyl group, a 2-propoxyethyl group, a 1-propoxy-1-methylethyl group, a 2-propoxy-1-methylethyl group, an isopropoxymethyl group, a 1-isopropoxyethyl group, a 2-isopropoxyethyl group, a butoxymethyl group, a sec-butoxymethyl group, an isobutoxymethyl group, and a tert-butoxymethyl group.

The number of carbon atoms in the alkoxy group in the alkoxyalkyl group is preferably 1 to 6, and more preferably 1 to 4.

The number of carbon atoms in the alkylene group in the alkoxyalkyl group is preferably 1 to 4, and more preferably 1 to 2.

The hydroxyalkyl group having 1 to 6 carbon atoms in the present invention may be any of a linear form, a branched form, and a cyclic form. Examples of the hydroxyalkyl group having 1 to 6 carbon atoms include a hydroxymethyl group, a 1-hydroxyethyl group, a 2-hydroxyethyl group, a 1-hydroxypropyl group, a 2-hydroxypropyl group, a 3-hydroxypropyl group, a 1-hydroxybutyl group, a 2-hydroxybutyl group, a 3-hydroxybutyl group, and a 4-hydroxybutyl group.

Examples of the halogen atom in the present invention include a fluorine atom, a chlorine atom, a bromine atom, and an iodine atom.

The number of halogen atoms in the alkyl group having 1 to 6 carbon atoms which may be substituted with a halogen atom of R¹³ may be 1 or 2 or more.

From the viewpoint of suitably obtaining the effect of the present invention, R¹¹ in the Formula (1X) is preferably an alkylene group having 1 to 3 carbon atoms, more preferably a methylene group or a 1,2-ethylene group.

From the viewpoint of suitably obtaining the effect of the present invention, R¹² in the Formula (1X) is preferably a hydrogen atom or an alkoxyalkyl group having 2 to 6 carbon atoms in total.

The repeating unit represented by Formula (1) contained in the polymer may be one kind or two or more kinds as long as Formula (1) is satisfied.

The polymer containing a repeating unit represented by Formula (1) may contain a repeating unit represented by the following Formula (2) as a repeating unit other than the repeating unit represented by the Formula (1).

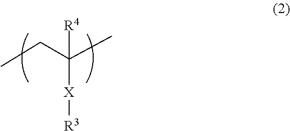

(In Formula (2), X represents a single bond or —COO—, R³ represents a monovalent organic group having 1 to 20 carbon atoms, and R⁴ represents a hydrogen atom or an alkyl group having 1 to 6 carbon atoms.)

R⁴ in Formula (2) is preferably a hydrogen atom or a methyl group.

R³ in Formula (2) is not particularly limited as long as R³ is a monovalent organic group having 1 to 20 carbon atoms.

Examples of R³ in Formula (2) include the following groups (i) to (iv).
(i) A linear or branched alkyl group having 1 to 20 carbon atoms
(ii) A substituent-containing linear or branched alkyl group having 1 to 20 carbon atoms in total
(iii) A monovalent group having 2 to 20 carbon atoms in total and having a cyclic structure optionally having a heteroatom
(iv) A monovalent group represented by the following Formula (2Y-1),

Note that specific examples may overlap between the above (i) to (iv).

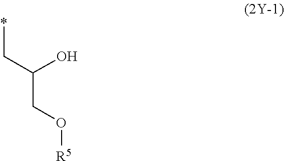

(In Formula (2Y-1), R⁵ represents a monovalent group having 1 to 15 carbon atoms in total. * represents an atomic bonding.)

Examples of the linear or branched alkyl group having 1 to 20 carbon atoms in (i) include a linear or branched alkyl group having 1 to 6 carbon atoms.

Examples of the substituent in (ii) include a hydroxy group, a carboxy group, and an aryl group. The number of substituents may be one or two or more. When there are two or more substituents, the two or more substituents may be the same or different.

Examples of the aryl group include a phenyl group, a naphthyl group, and an anthracenyl group.

Examples of the monovalent group having 2 to 20 carbon atoms in total and having a cyclic structure optionally having a heteroatom in (iii) include the following (iii-1) to (iii-3).
(iii-1) A monovalent group obtained by removing one hydrogen atom from lactone ring of cyclic ester compound optionally having a substituent
(iii-2) A monovalent group which contains an aliphatic ring in which a carbon-carbon bond is optionally interrupted by a heteroatom, which is an aliphatic ring which is optionally substituted with a substituent
(iii-3) An aromatic group optionally having a substituent

Examples of the lactone ring in (iii-1) include a 3-membered to 7-membered lactone ring.

Examples of the substituent in (iii-1) include a hydroxy group, an alkyl group having 1 to 10 carbon atoms, an alkoxy group having 1 to 10 carbon atoms, an acyloxy group having 1 to 10 carbon atoms, and a carboxy group. The number of substituents may be one or two or more. When there are two or more substituents, the two or more substituents may be the same or different.

The phrase “a carbon-carbon bond is optionally interrupted by a heteroatom” in (iii-2) means that an —O— bond or an —S— bond is included between carbon-carbon bonds of an aliphatic ring.

The aliphatic ring which is optionally substituted with a substituent means that all or some of hydrogen atoms of the aliphatic ring are substituted with, for example, a hydroxy group, a linear or branched alkyl group having 1 to 10 carbon atoms, an alkoxy group having 1 to 20 carbon atoms, an acyloxy group having 1 to 10 carbon atoms, or a carboxy group. When there are two or more substituents, the two or more substituents may be the same or different.

As the group (iii-2), a monovalent group obtained by removing one hydrogen atom from the aliphatic ring of the aliphatic cyclic compound which is an aliphatic cyclic compound having an aliphatic ring in which a carbon-carbon bond is optionally interrupted by a heteroatom and in which the aliphatic ring is optionally substituted with a substituent is preferable.

The aliphatic ring is preferably a monocyclic or polycyclic aliphatic ring having 3 to 10 carbon atoms.

Examples of the “monocyclic or polycyclic aliphatic ring having 3 to 10 carbon atoms” include cyclopropane, cyclobutane, cyclopentane, cyclohexane, cyclohexene, cycloheptane, cyclooctane, cyclononane, cyclodecane, spiro bicyclopentane, bicyclo[2.1.0]pentane, bicyclo[3.2.1]octane, tricyclo[3.2.1.02, 7]octane, spiro[3,4]octane, norbornane, norbornene, and tricyclo[3.3.1.13, 7]decane (adamantane).

The polycyclic aliphatic ring is preferably a bicyclo ring or a tricyclo ring.

Among them, examples of the bicyclo ring include norbornane, norbornene, spiro bicyclopentane, bicyclo[2.1.0]pentane, bicyclo[3.2.1]octane, and spiro[3,4]octane.

Among them, examples of the tricyclo ring include tricyclo[3.2.1.02, 7]octane and tricyclo[3.3.1.13, 7]decane (adamantane).

The aliphatic ring preferably has at least one unsaturated bond (for example, a double bond or a triple bond). The aliphatic ring preferably has one to three unsaturated bonds. The aliphatic ring preferably has one or two unsaturated bonds. The unsaturated bond is preferably a double bond.

The aromatic ring in the aromatic group optionally having a substituent that is (iii-3) may be an aromatic hydrocarbon ring or an aromatic heterocyclic ring. Examples of the aromatic hydrocarbon ring include a benzene ring, a naphthalene ring, and an anthracene ring.

Examples of the aromatic group which optionally has a substituent include a group represented by the following Formula (Ar2).

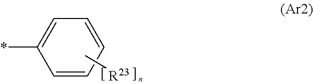

(In Formula (Ar2), R²³ represents a halogen atom or an alkyl group having 1 to 6 carbon atoms which may be substituted with a halogen atom. n represents an integer of 0 to 5. When there are two or more R²³, two or more R²³ may be the same or different. * represents an atomic bonding.)

Examples of the repeating unit represented by Formula (2) when R³ in Formula (2) is a group of (i) include the following repeating units.

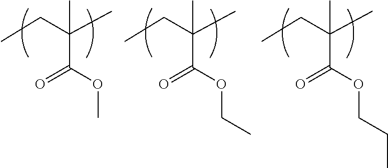

Examples of the repeating unit represented by Formula (2) when R in Formula (2) is a group of (ii) include the following repeating units.

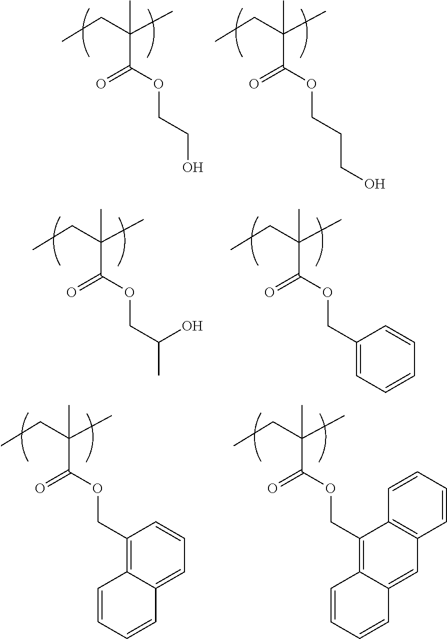

Examples of the repeating unit represented by Formula (2) when R in Formula (2) is a group of (iii) include the following repeating units.

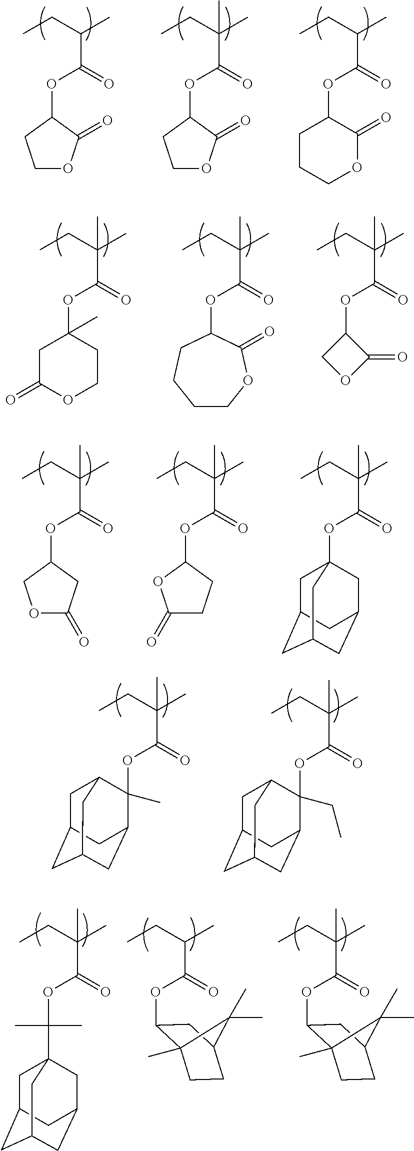

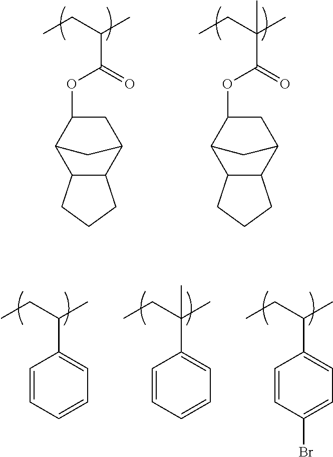

Examples of the repeating unit represented by Formula (2) when R³ in Formula (2) is a group of (iv) include the following repeating units.

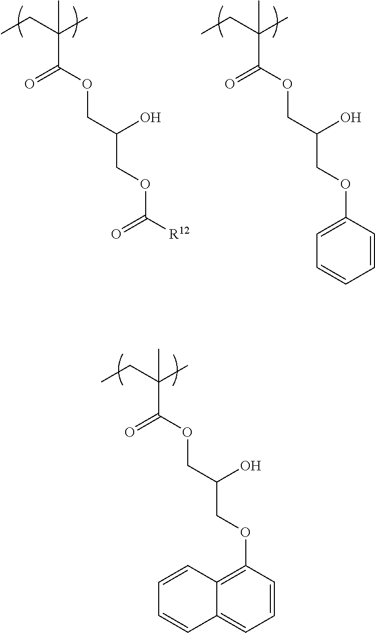

(R¹² represents an alkyl group having 1 to 6 carbon atoms.)

X in Formula (2) preferably represents —COO—.

R³ in Formula (2) preferably represents the following Formula (2X).

When R¹ in Formula (1) is other than the Formula (1X) (for example, an alkyl group having 1 to 6 carbon atoms, a hydroxyalkyl group having 1 to 6 carbon atoms, a group represented by Formula (Ar1), and the like), it is preferable that X in Formula (2) is —COO— and R³ represents the following Formula (2X).

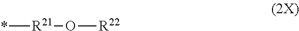

(In Formula (2X), R²¹ represents an alkylene group having 1 to 4 carbon atoms, and R²² represents a hydrogen atom, an alkyl group having 1 to 6 carbon atoms, or an alkoxyalkyl group having 2 to 10 carbon atoms in total. * represents an atomic bonding.)

The alkylene group having 1 to 4 carbon atoms in R²¹ is preferably an alkylene group having 1 to 3 carbon atoms, and more preferably a methylene group, a 1,2-ethylene group, or a propylene group. The propylene group may be a 1,3-propylene group or a 1,2-propylene group.

When X in Formula (2) represents —COO— and R³ represents Formula (2X), Formula (2) is represented by, for example, the following Formula (2X-1).

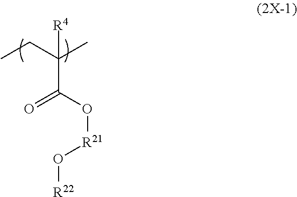

(In Formula (2X-1), R⁴ represents a hydrogen atom or an alkyl group having 1 to 6 carbon atoms, R²¹ represents an alkylene group having 1 to 4 carbon atoms, and R²² represents a hydrogen atom, an alkyl group having 1 to 6 carbon atoms, or an alkoxyalkyl group having 2 to 10 carbon atoms in total.)

The molar ratio of the repeating unit represented by Formula (1) to the repeating unit represented by Formula (2) (Formula (1):Formula (2)) in the polymer containing the repeating unit represented by the Formula (1) is not particularly limited, but is preferably 30:70 to 90:10, and more preferably 50:50 to 90:10.

The method for manufacturing a polymer containing the repeating unit represented by Formula (1) is not particularly limited.

For example, a monomer containing a compound represented by the following Formula (1A) corresponding to the repeating unit represented by Formula (1) can be polymerized.

The monomer may contain a compound represented by the following Formula (2A) corresponding to the repeating unit represented by Formula (2) as necessary.

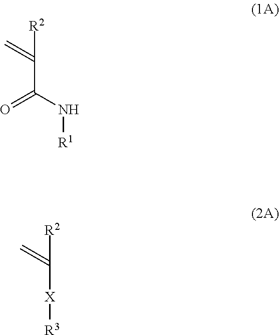

When the polymer contains a repeating unit represented by Formula (1) in a case where R¹ in Formula (1) is a group represented by Formula (1X), the polymer can also be obtained by polymerizing a monomer containing a compound represented by Formula (1A) in which R¹ is a group represented by Formula (1X) and R¹² in Formula (1X) is a hydrogen atom in the presence of a solvent represented by the following Formula (3A). During this polymerization, R¹² in the group represented by Formula (1X) in the compound represented by Formula (1A) is substituted with R¹² in Formula (3A). This substitution may occur in all or some of the compounds represented by Formula (1A) used for polymerization.

When the polymer contains a repeating unit represented by Formula (2) in a case where R³ in Formula (2) is a group represented by Formula (2X), the polymer can also be obtained by polymerizing a monomer containing a compound represented by Formula (2A) in which R³ is a group represented by Formula (2X) and R²² in Formula (2X) is a hydrogen atom in the presence of a solvent represented by the following Formula (3A). During this polymerization, R²² in the group represented by Formula (2X) in the compound represented by Formula (2A) is substituted with R¹² in Formula (3A). This substitution may occur in all or some of the compounds represented by Formula (2A) used for polymerization.

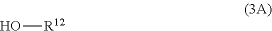

(In Formula (3A), R¹² represents an alkoxyalkyl group having 2 to 10 carbon atoms in total.)

Examples of the solvent represented by Formula (3A) include propylene glycol monomethyl ether.

The molecular weight of the polymer containing the repeating unit represented by Formula (1) is not particularly limited, but the weight average molecular weight by gel permeation chromatography is preferably 5,000 to 100,000, and more preferably 10,000 to 50,000.

The content of the polymer containing the repeating unit represented by Formula (1) in the composition for forming a resist underlayer film for EB or EUV lithography is not particularly limited, but is preferably 50% by mass to 100% by mass, more preferably 60% by mass to 99% by mass, and particularly preferably 70% by mass to 99% by mass with respect to the film forming component.

The film forming component is a component remaining in a resist underlayer film when a resist underlayer film for EB or EUV lithography (hereinafter may be simply referred to as a “resist underlayer film:”) is formed from the composition for forming a resist underlayer film. Examples of the film forming component include a component present in the resist underlayer film as it is, a component present in the resist underlayer film as a reaction product with other components, and a component used as an auxiliary agent (for example, a curing catalyst) that assists the reaction of other components.

In other words, the film forming component is a generic term for components other than the solvent among all the components of the composition for forming a resist underlayer film.

### <Crosslinking Agent>

The composition for forming a resist underlayer film preferably contains a crosslinking agent from the viewpoint of suitably obtaining the effect of the present invention.

The crosslinking agent contained as an optional component in the composition for forming a resist underlayer film has a functional group that reacts alone or has a functional group that reacts with an N—R¹—O—R² group in the repeating unit represented by Formula (1) in the polymer.

Examples of the crosslinking agent include hexamethoxymethylmelamine, tetramethoxymethylbenzoguanamine, 1,3,4,6-tetrakis(methoxymethyl)glycoluril (tetramethoxymethyl glycoluril) (POWDERLINK [registered trademark] 1174), 1,3,4,6-tetrakis(butoxymethyl)glycoluril, 1,3,4,6-tetrakis(hydroxymethyl)glycoluril, 1,3-bis(hydroxymethyl)urea, 1,1,3,3-tetrakis(butoxymethyl)urea, and 1,1,3,3-tetrakis(methoxymethyl)urea.

In addition, the crosslinking agent may be a nitrogen-containing compound having 2 to 6 substituents represented by the following Formula (1d) that bond to a nitrogen atom in one molecule, which is described in WO2017/187969A.

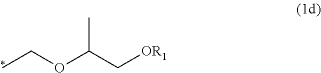

(In Formula (1d), R₁ represents a methyl group or an ethyl group. * represents an atomic bonding bonded to a nitrogen atom.)

The nitrogen-containing compound having 2 to 6 substituents represented by Formula (1d) in one molecule may be a glycoluril derivative represented by the following Formula (1E).

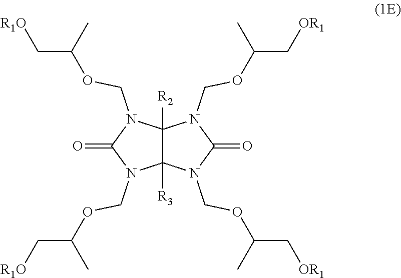

(In Formula (1E), four R₁ each independently represent a methyl group or an ethyl group, and R₂ and R₃ each independently represent a hydrogen atom, an alkyl group having 1 to 4 carbon atoms, or a phenyl group.)

Examples of the glycoluril derivative represented by the Formula (1E) include compounds represented by the following formulas (1E-1) to (1E-6).

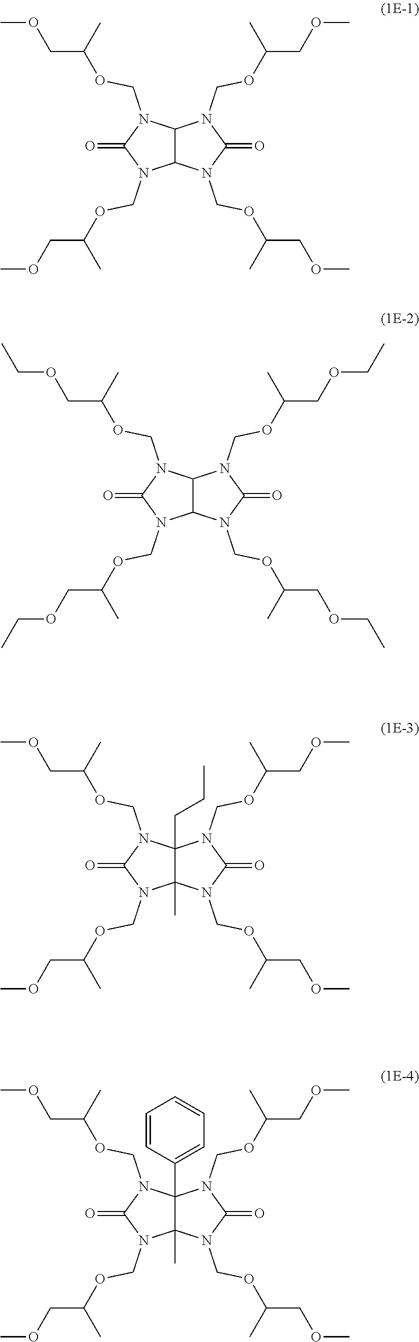

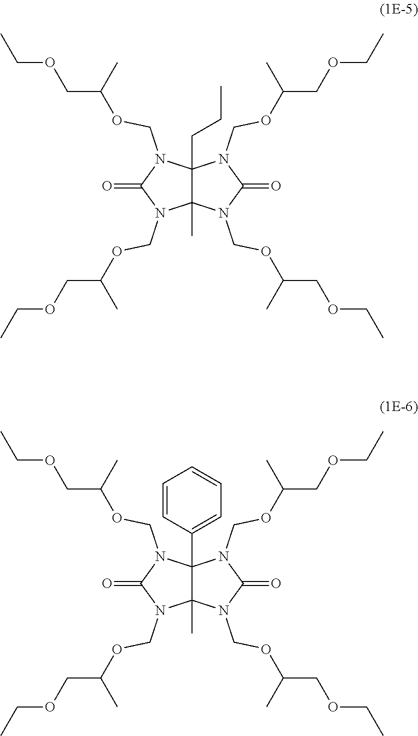

The nitrogen-containing compound having 2 to 6 substituents represented by the Formula (1d) in one molecule is obtained by reacting a nitrogen-containing compound having 2 to 6 substituents represented by the following Formula (2d) that bond to a nitrogen atom in one molecule with at least one compound represented by the following Formula (3d).

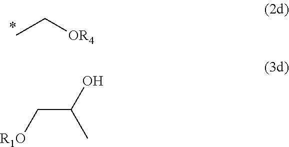

(In Formula (2d) and Formula (3d), R₁ represents a methyl group or an ethyl group, and R₄ represents an alkyl group having 1 to 4 carbon atoms. * represents an atomic bonding bonded to a nitrogen atom.)

The glycoluril derivative represented by the Formula (1E) is obtained by reacting a glycoluril derivative represented by the following Formula (2E) with at least one compound represented by the Formula (3d).

The nitrogen-containing compound having 2 to 6 substituents represented by the Formula (2d) in one molecule is, for example, a glycoluril derivative represented by the following Formula (2E).

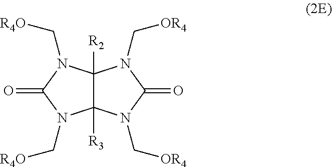

(In Formula (2E), R₂ and R₃ each independently represent a hydrogen atom, an alkyl group having 1 to 4 carbon atoms, or a phenyl group, and R₄ each independently represents an alkyl group having 1 to 4 carbon atoms.)

Examples of the glycoluril derivative represented by the Formula (2E) include compounds represented by the following Formulas (2E-1) to (2E-4). Furthermore, examples of the compound represented by the Formula (3d) include compounds represented by the following formulas (3d-1) and (3d-2).

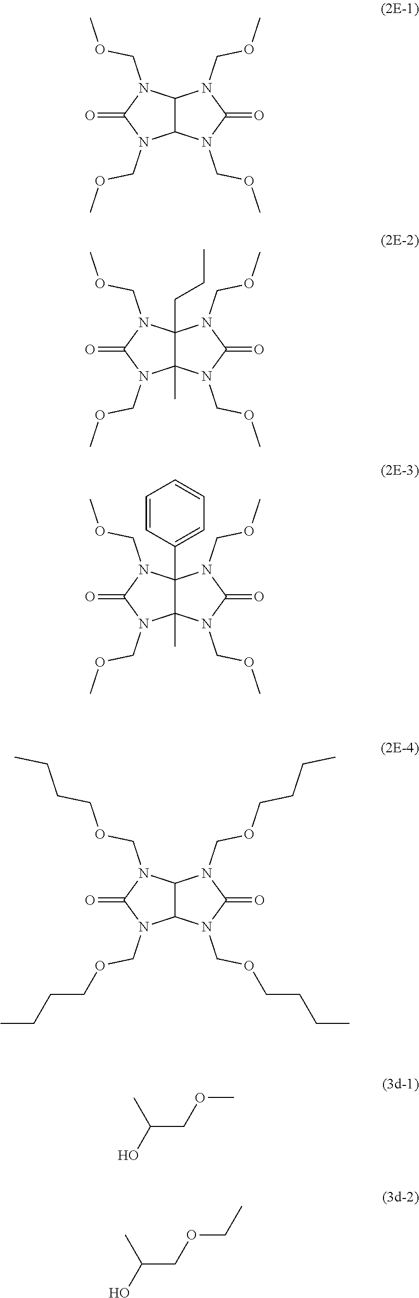

For the content related to the nitrogen-containing compound having 2 to 6 substituents represented by Formula (1d) that bond to a nitrogen atom in one molecule, the entire disclosure of WO2017/187969 is incorporated in the present application.

When the crosslinking agent is used, the content ratio of the crosslinking agent in the composition for forming a resist underlayer film for EB or EUV lithography is, for example, 1% by mass to 50% by mass, preferably 5% by mass to 40% by mass with respect to the polymer containing the repeating unit represented by Formula (1).

### <Curing Catalyst>

As the curing catalyst contained as an optional component in the composition for forming a resist underlayer film, both a thermal acid generator and a photoacid generator can be used, but it is preferable to use a thermal acid generator.

Examples of the thermal acid generator include sulfonic acid compounds and carboxylic acid compounds such as p-toluenesulfonic acid, trifluoromethanesulfonic acid, pyridinium-p-toluenesulfonate (pyridinium-p-toluenesulfonic acid), pyridinium phenol sulfonic acid, pyridinium-p-hydroxybenzenesulfonic acid (p-phenolsulfonic acid pyridinium salt), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid, and hydroxybenzoic acid.

Examples of the photoacid generator include an onium salt compound, a sulfonimide compound, and a disulfonyl diazomethane compound.

Examples of the onium salt compound include iodonium salt compounds such as diphenyliodonium hexafluorophosphate, diphenyliodonium trifluoromethanesulfonate, diphenyliodonium nonafluoronormalbutanesulfonate, diphenyliodonium perfluoronormaloctanesulfonate, diphenyliodonium camphorsulfonate, bis(4-tert-butylphenyl)iodonium camphorsulfonate, and bis(4-tert-butylphenyl)iodonium trifluoromethanesulfonate; and sulfonium salt compounds such as triphenylsulfonium hexafluoroantimonate, triphenylsulfonium nonafluoronormalbutanesulfonate, triphenylsulfonium camphorsulfonate, and triphenylsulfonium trifluoromethanesulfonate.

Examples of the sulfonimide compound include N-(trifluoromethanesulfonyloxy) succinimide, N-(nonafluoronormalbutanesulfonyloxy)succinimide, N-(camphorsulfonyloxy)succinimide, and N-(trifluoromethanesulfonyloxy)naphthalimide.

Examples of the disulfonyl diazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyl diazomethane.

Only one kind of curing catalyst can be used, or two or more kinds thereof can be used in combination.

When a curing catalyst is used, the content ratio of the curing catalyst is, for example, 0.1% by mass to 50% by mass, preferably 1% by mass to 30% by mass with respect to the crosslinking agent.

### <Solvent>

As the solvent, an organic solvent generally used for a chemical solution for a semiconductor lithography process is preferable. Specifically, examples thereof include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2 pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-ethoxypropionate, methyl 3-ethoxypropionate, ethyl 3-methoxypropionate, methyl pyruvate, ethyl pyruvate, ethyl acetate, butyl acetate, ethyl lactate, butyl lactate, 2-heptanone, methoxy cyclopentane, anisole, γ-butyrolactone, N-methylpyrrolidone, N,N-dimethylformamide, and N,N-dimethylacetamide. These solvents can be used alone or in combination of two or more kinds thereof.

Among these solvents, propylene glycol monomethyl ether, propylene glycol monomethyl ether acetate, ethyl lactate, butyl lactate, and cyclohexanone are preferable. In particular, propylene glycol monomethyl ether and propylene glycol monomethyl ether acetate are preferable.

### <Other Components>

In the composition for forming a resist underlayer film, a surfactant can be further added in order to further improve the coating property for surface unevenness without generating pinholes, striations, and the like.

Examples of the surfactant include nonionic surfactants such as polyoxyethylene alkyl ethers (for example, polyoxyethylene lauryl ether, polyoxyethylene stearyl ether, polyoxyethylene cetyl ether, and polyoxyethylene oleyl ether), polyoxyethylene alkyl allyl ethers (for example, polyoxyethylene octylphenol ether and polyoxyethylene nonylphenol ether), polyoxyethylene/polyoxypropylene block copolymers, sorbitan fatty acid esters (for example, sorbitan monolaurate, sorbitan monopalmitate, sorbitan monostearate, sorbitan monooleate, sorbitan trioleate, and sorbitan tristearate), polyoxyethylene sorbitan fatty acid esters (for example, polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate); fluorinated surfactants such as F-top EF301, EF303, and EF352 (manufactured by TOHKEM PRODUCTS Corporation, product name), Megaface F171, F173, and R-30 (manufactured by DIC Corporation, product name), Fluorad FC430 and FC431 (Sumitomo 3M Co., Ltd., product name), AsahiGuard AG710, and Surflon S-382, SC101, SC102, SC103, SC104, SC105, and SC106 (manufactured by Asahi Glass Co., Ltd., product name); and organosiloxane polymer KP341 (manufactured by Shin-Etsu Chemical Co., Ltd.)

The blending amount of these surfactants is not particularly limited, but is usually 2.0% by mass or less, and preferably 1.0% by mass or less with respect to the total solid content of the composition for forming a resist underlayer film.

These surfactants may be added alone, or may be added in combination of two or more thereof.

The film forming component contained in the composition for forming a resist underlayer film, that is, the component excluding the solvent is, for example, 0.01% by mass to 10% by mass of the composition for forming a resist underlayer film.

The composition for forming a resist underlayer film for EB or EUV lithography is preferably used for forming a resist underlayer film for EB or EUV lithography having a film thickness of 10 nm or less.

### (Resist Underlayer Film for EB or EUV Lithography)

The resist underlayer film for EB or EUV lithography (hereinafter may be simply referred to as a “resist underlayer film”) of the present invention is a cured product of the above-described composition for forming a resist underlayer film for EB or EUV lithography.

The resist underlayer film can be manufactured, for example, by applying the above-described composition for forming a resist underlayer film for EB or EUV lithography onto a semiconductor substrate and firing the composition.

Examples of the semiconductor substrate to which the composition for forming a resist underlayer film is applied include silicon wafers, germanium wafers, and compound semiconductor wafers such as gallium arsenide, indium phosphide, gallium nitride, indium nitride, and aluminum nitride.

When a semiconductor substrate having an inorganic film formed on a surface thereof is used, the inorganic film is formed by, for example, an atomic layer deposition (ALD) method, a chemical vapor deposition (CVD) method, a reactive sputtering method, an ion plating method, a vacuum deposition method, or a spin coating method (spin on glass: SOG). Examples of the inorganic film include a polysilicon film, a silicon oxide film, a silicon nitride film, a boro-phospho silicate glass (BPSG) film, a titanium nitride film, a titanium nitride oxide film, a tungsten film, a gallium nitride film, and a gallium arsenide film.

The composition for forming a resist underlayer film of the present invention is applied onto such a semiconductor substrate by an appropriate application method such as a spinner or a coater. Thereafter, baking is performed using heating means such as a hot plate to form a resist underlayer film. The baking conditions are appropriately selected from a baking temperature of 100° C. to 400° C. and a baking time of 0.3 minutes to 60 minutes. Preferably, the baking temperature is 120° C. to 350° C. and the baking time is 0.5 minutes to 30 minutes, and more preferably, the baking temperature is 150° C. to 300° C. and the baking time is 0.8 minutes to 10 minutes.

The film thickness of the resist underlayer film is preferably 10 nm or less, more preferably 9 nm or less, still more preferably 8 nm or less, and particularly preferably 7 nm or less from the viewpoint of suitably obtaining the effect of the present invention. In addition, the film thickness of the resist underlayer film may be 1 nm or more, 2 nm or more, or 3 nm or more.

The film thickness of the resist underlayer film is, for example, 0.001 μm (1 nm) to 10 μm, 0.002 μm (2 nm) to 1 μm, 0.005 μm (5 nm) to 0.5 μm (500 nm), 0.001 μm (1 nm) to 0.05 μm (50 nm), 0.002 μm (2 nm) to 0.05 μm (50 nm), 0.003 μm (3 nm) to 0.05 μm (50 nm), 0.004 μm (4 nm) to 0.05 μm (50 nm), 0.005 μm (5 nm) to 0.05 μm (50 nm), 0.003 μm (3 nm) to 0.03 μm (30 nm), 0.003 μm (3 nm) to 0.02 μm (20 nm), 0.005 μm (5 nm) to 0.02 μm (20 nm), 0.005 μm (5 nm) to 0.02 μm (20 nm), 0.003 μm (3 nm) to 0.01 μm (10 nm), 0.005 μm (5 nm) to 0.01 μm (10 nm), 0.003 μm (3 nm) to 0.006 μm (6 nm), or 0.005 μm (5 nm).

The method of measuring the film thickness of the resist underlayer film in the present specification is as follows.
Name of measuring apparatus: Ellipso type film thickness measuring apparatus RE-3100 (SCREEN Holdings Co., Ltd.)
SWE (Single Wavelength Ellipsometer) Mode
Arithmetic average of 8 points (for example, 8 points are measured at intervals of 1 cm in the wafer X direction.)

### (Substrate for Semiconductor Processing)

A substrate for semiconductor processing of the present invention includes a semiconductor substrate and a resist underlayer film for EB or EUV lithography of the present invention.

Examples of the semiconductor substrate include the above-described semiconductor substrate.

The resist underlayer film is disposed, for example, on a semiconductor substrate.

### (Method for Manufacturing Semiconductor Element, Pattern Forming Method, and Method for Improving LWR of Resist Pattern)

The method for manufacturing a semiconductor element of the present invention includes at least the following steps.
a step of forming a resist underlayer film on a semiconductor substrate using the composition for forming a resist underlayer film for EB or EUV lithography of the present invention; and
a step of forming a resist film on the resist underlayer film using a resist for EB or EUV lithography.

The pattern forming method of the present invention includes at least the following steps.
a step of forming a resist underlayer film on a semiconductor substrate using the composition for forming a resist underlayer film for EB or EUV lithography of the present invention;
a step of forming a resist film on the resist underlayer film using a resist for EB or EUV lithography;
a step of irradiating the resist film with EB or EUV, and then developing the resist film to obtain a resist pattern; and
a step of etching a resist underlayer film using the resist pattern as a mask.

The method for improving LWR of a resist pattern of the present invention includes at least the following steps.
a step of forming a resist underlayer film on a semiconductor substrate using the composition for forming a resist underlayer film for EB or EUV lithography of the present invention;
a step of forming a resist film on the resist underlayer film using a resist for EB or EUV lithography;
and
a step of irradiating the resist film with EB or EUV, and then developing the resist film to obtain a resist pattern.

In the method for improving LWR of a resist pattern, by using a resist underlayer film obtained from the composition for forming a resist underlayer film for EB or EUV lithography of the present invention under a resist film, it is possible to improve non-uniformity (line width roughness (LWR)) of a resist pattern width in EB or EUV lithography.

Usually, a resist film is formed on the resist underlayer film.

The film thickness of the resist film is preferably 200 nm or less, more preferably 150 nm or less, still more preferably 100 nm or less, particularly preferably 80 nm or less. In addition, the film thickness of the resist film may be 5 nm or more, 10 nm or more, or 15 nm or more.

The resist formed on the resist underlayer film by coating and firing by a known method is not particularly limited as long as the resist responds to EB or EUV used for irradiation. Both a negative photoresist and a positive photoresist can be used.

In the present specification, a resist responding to EB is also referred to as a photoresist.

Examples of the photoresist include a positive photoresist composed of a novolak resin and 1,2-naphthoquinone diazide sulfonic acid ester; a chemically amplified photoresist composed of a binder having a group which is decomposed by an acid to increase the alkali dissolution rate; a chemically amplified photoresist composed of a low molecular compound which is decomposed by an acid to increase the alkali dissolution rate of the photoresist, an alkali-soluble binder, and a photoacid generator; a chemically amplified photoresist consisting of a binder that has a group that decomposes with acid to increase the alkali dissolution rate, a low molecular compound that decomposes with acid to increase the alkali dissolution rate of the photoresist, and a photoacid generator; and a resist containing metal elements. Examples thereof include product name V146G manufactured by JSR Corporation, product name APEX-E manufactured by Shipley, product name PAR710 manufactured by Sumitomo Chemical Co., Ltd., and product names AR2772 and SEPR430 manufactured by Shin-Etsu Chemical Co., Ltd. Further, examples thereof include a fluorine-containing atomic polymer-based photoresist as described in Proc. SPIE, Vol. 3999, 330-334 (2000), Proc. SPIE, Vol. 3999, 357-364 (2000), or Proc. SPIE, Vol. 3999, 365-374 (2000).

In addition, so-called resist compositions, metal-containing resist compositions such as resist compositions, radiation-sensitive resin compositions, high-resolution patterning compositions based on organometallic solutions described in WO2019/188595, WO2019/187881, WO2019/187803, WO2019/167737, WO2019/167725, WO2019/187445, WO2019/167419, WO2019/123842, WO2019/054282, WO2019/058945, WO2019/058890, WO2019/039290, WO2019/044259, WO2019/044231, WO2019/026549, WO2018/193954, WO2019/172054, WO2019/021975, WO2018/230334, WO2018/194123, JP 2018-180525, WO2018/190088, JP 2018-070596, JP 2018-028090 A, JP 2016-153409 A, JP 2016-130240 A, JP 2016-108325 A, JP 2016-047920 A, JP 2016-035570 A, JP 2016-035567 A, JP 2016-035565 A, JP 2019-101417 A, JP 2019-117373 A, JP 2019-052294 A, JP 2019-008280 A, JP 2019-008279 A, JP 2019-003176 A, JP 2019-003175 A, JP 2018-197853 A, JP 2019-191298 A, JP 2019-061217 A, JP 2018-045152 A, JP 2018-022039 A, JP 2016-090441 A, JP 2015-10878 A, JP 2012-168279 A, JP 2012-022261 A, JP 2012-022258 A, JP 2011-043749 A, JP 2010-181857 A, JP 2010-128369 A, WO2018/031896, JP 2019-113855, WO2017/156388, WO2017/066319, JP 2018-41099 A, WO2016/065120, WO2015/026482, JP 2016-29498 A, and JP 2011-253185 A, but not limited thereto, can be used.

Examples of the resist composition include the following compositions.

An active ray-sensitive or radiation-sensitive resin composition including: a resin A having a repeating unit having an acid-decomposable group in which a polar group is protected by a protecting group that is desorbed by the action of an acid; and a compound represented by the following general Formula (21).

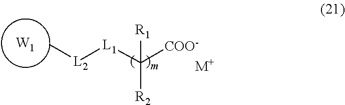

In the general Formula (21), m represents an integer of 1 to 6.
R₁ and R₂ each independently represent a fluorine atom or a perfluoroalkyl group.
L₁ represents —O—, —S—, —COO—, —SO₂—, or —SO₃—.
L₂ represents an alkylene group optionally having a substituent or a single bond.
W₁ represents a cyclic organic group which may have a substituent.
M⁺ represents a cation.

A metal-containing film-forming composition for extreme ultraviolet ray or electron beam lithography, containing: a compound having a metal-oxygen covalent bond; and a solvent, in which metal elements constituting the compound belong to the third to seventh periods of Groups 3 to 15 of the periodic table.

A radiation-sensitive resin composition containing: a polymer having a first structural unit represented by the following Formula (31) and a second structural unit represented by the following Formula (32) and containing an acid-dissociable group; and an acid generator.

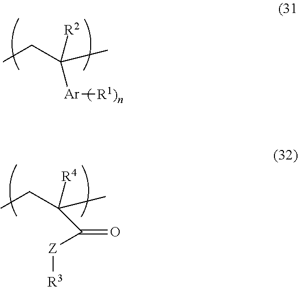

(In Formula (31), Ar is a group obtained by removing (n+1) hydrogen atoms from an arene having 6 to 20 carbon atoms. R¹ is a hydroxy group, a sulfanyl group, or a monovalent organic group having 1 to 20 carbon atoms. n is an integer of 0 to 11. When n is 2 or more, a plurality of R¹ are the same or different. R² is a hydrogen atom, a fluorine atom, a methyl group, or a trifluoromethyl group. In Formula (32), R³ is a monovalent group having 1 to 20 carbon atoms and containing the acid-dissociable group. Z is a single bond, an oxygen atom or a sulfur atom. R⁴ is a hydrogen atom, a fluorine atom, a methyl group, or a trifluoromethyl group.)

A resist composition containing: a resin (A1) containing a structural unit having a cyclic carbonate structure, a structural unit represented by the following formula, and a structural unit having an acid-unstable group; and an acid generator.

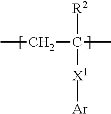

[In the formula,
R² represents an alkyl group having 1 to 6 carbon atoms optionally having a halogen atom, a hydrogen atom, or a halogen atom, X¹ represents a single bond, —CO—O—*, or —CO—NR⁴—*, * represents an atomic bonding with —Ar, R⁴ represents a hydrogen atom or an alkyl group having 1 to 4 carbon atoms, and Ar represents an aromatic hydrocarbon group having 6 to 20 carbon atoms which may have one or more groups selected from the group consisting of a hydroxy group and a carboxyl group.]

Examples of the resist film include the following.

A resist film containing a base resin containing a repeating unit represented by the following Formula (a1) and/or a repeating unit represented by the following Formula (a2), and a repeating unit that generates an acid bonded to a polymer main chain by exposure.

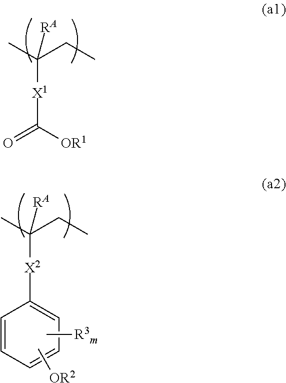

(In Formula (a1) and Formula (a2), R^{A} is each independently a hydrogen atom or a methyl group. R¹ and R² are each independently a tertiary alkyl group having 4 to 6 carbon atoms. R³ each independently represent a fluorine atom or a methyl group. m is an integer of 0 to 4. X¹ is a single bond, a phenylene group or a naphthylene group, or a linking group having 1 to 12 carbon atoms containing at least one selected from an ester bond, a lactone ring, a phenylene group and a naphthylene group. X² is a single bond, an ester bond, or an amide bond.)

Examples of the resist material include the following.

A resist material containing a polymer having a repeating unit represented by the following Formula (b1) or Formula (b2).

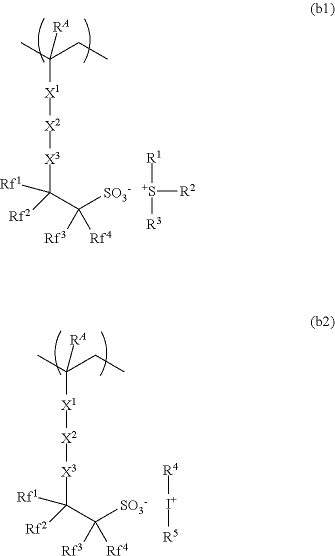

(In Formula (b1) and Formula (b2), R^{A} is a hydrogen atom or a methyl group. X¹ is a single bond or an ester group. X² is a linear, branched or cyclic alkylene group having 1 to 12 carbon atoms or an arylene group having 6 to 10 carbon atoms, and a part of the methylene group constituting the alkylene group may be substituted with an ether group, an ester group or a lactone ring-containing group, and at least one hydrogen atom contained in X² is substituted with a bromine atom. X³ is a single bond, an ether group, an ester group, or a linear, branched or cyclic alkylene group having 1 to 12 carbon atoms, and a part of the methylene group constituting the alkylene group may be substituted with an ether group or an ester group. Rf¹ to Rf⁴ are each independently a hydrogen atom, a fluorine atom, or a trifluoromethyl group, and at least one of Rf¹ to Rf⁴ is a fluorine atom or a trifluoromethyl group. In addition, Rf¹ and Rf² may be combined to form a carbonyl group. R¹ to R⁵ are each independently a linear, branched or cyclic alkyl group having 1 to 12 carbon atoms, a linear, branched or cyclic alkenyl group having 2 to 12 carbon atoms, an alkynyl group having 2 to 12 carbon atoms, an aryl group having 6 to 20 carbon atoms, an aralkyl group having 7 to 12 carbon atoms, or an aryloxyalkyl group having 7 to 12 carbon atoms, and some or all of hydrogen atoms of these groups may be substituted with a hydroxy group, a carboxy group, a halogen atom, an oxo group, a cyano group, an amide group, a nitro group, a sultone group, a sulfone group, or a sulfonium salt-containing group, and some of methylene groups constituting these groups may be substituted with an ether group, an ester group, a carbonyl group, a carbonate group, or a sulfonic acid ester group. R¹ and R² may be bonded to each other to form a ring together with the sulfur atom to which R¹ and R² are bonded.)

A resist material containing a base resin containing a polymer containing a repeating unit represented by the following Formula (a).

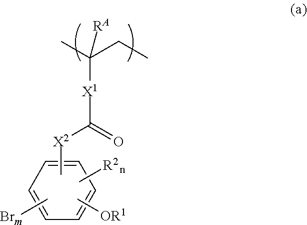

(In Formula (a), R^{A} is a hydrogen atom or a methyl group. R¹ is a hydrogen atom or an acid-unstable group. R² is a linear, branched or cyclic alkyl group having 1 to 6 carbon atoms or a halogen atom other than bromine. X¹ is a single bond or a phenylene group, or a linear, branched, or cyclic alkylene group having 1 to 12 carbon atoms which may contain an ester group or a lactone ring. X² is —O—, —O—CH₂—, or —NH—. m is an integer of 1 to 4. u is an integer of 0 to 3. Here, m+u is an integer of 1 to 4.)

A resist composition which generates an acid by exposure and has solubility in a developer changed by an action of the acid, the resist composition containing: a base material component (A) of which solubility in a developer is changed by an action of an acid and a fluorine additive component (F) which exhibits decomposability in an alkaline developer, in which
the fluorine additive component (F) contains a fluororesin component (F1) having a constituent unit (f1) containing a base dissociable group and a constituent unit (f2) containing a group represented by the following general Formula (f2-(r-1)).

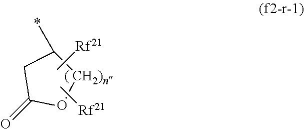

[In Formula (f2-(r-1)), Rf²¹ each independently represent a hydrogen atom, an alkyl group, an alkoxy group, a hydroxyl group, a hydroxyalkyl group, or a cyano group. n″ is an integer of 0 to 2. * is an atomic bonding.]

The constituent unit (f1) includes a constituent unit represented by the following general Formula (f1-1) or a constituent unit represented by the following general Formula (f1-2).

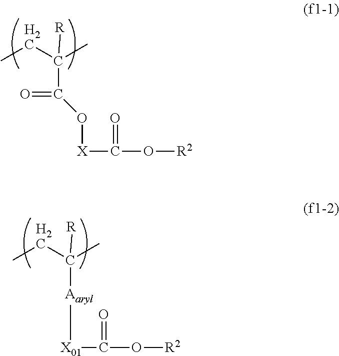

[In Formulas (f1-1) and (f1-2), R each independently represent a hydrogen atom, an alkyl group having 1 to 5 carbon atoms, or a halogenated alkyl group having 1 to 5 carbon atoms. X is a divalent linking group having no acid-dissociable site. A_{aryl} is a divalent aromatic cyclic group which may have a substituent. X₀₁ is a single bond or a divalent linking group. R² is each independently an organic group having a fluorine atom.]

Examples of the coating, the coating solution, and the coating composition include the following.

A coating containing a metal oxo-hydroxo network having organic ligands via metal carbon bonds and/or metal carboxylate bonds.

Inorganic oxo/hydroxo based compositions.

A coating solution containing: an organic solvent; a first organometallic composition represented by the formula R_{z}SnO_{(2-(z/2)-(x/2)}(OH)ₓ (where 0<z≤2 and 0<(z+x)≤4), the formula R′ₙSnX₄₋ₙ (where n=1 or 2), or mixtures thereof, in which R and R′ are independently a hydrocarbyl group having 1 to 31 carbon atoms, and X is a ligand having a hydrolysable bond to Sn or a combination thereof; and a hydrolyzable metal compound represented by the formula MX′v (where M is a metal selected from the group 2 to 16 of the periodic table of elements, v=a number from 2 to 6, and X′ is a ligand having a hydrolysable M-X bond or a combination thereof.).

A coating solution containing an organic solvent and a first organometallic compound represented by the formula RSnO_{(3/2-x/2)}(OH)ₓ (where 0<x<3), in which the solution contains from approximately 0.0025 M to about 1.5 M tin, R is an alkyl group or a cycloalkyl group having 3 to 31 carbon atoms, and the alkyl or cycloalkyl group is bonded to tin at a secondary or tertiary carbon atom.

An inorganic pattern forming precursor aqueous solution containing a mixture of water, a metal suboxide cation, a polyatomic inorganic anion, and a radiation-sensitive ligand containing a peroxide group.

The irradiation with EB or EUV is performed, for example, through a mask (reticle) for forming a predetermined pattern. The composition for forming a resist underlayer film of the present invention is applied for EB (electron beam) or EUV (extreme ultraviolet: 13.5 nm) irradiation, but is preferably applied for EUV (extreme ultraviolet) exposure.

The irradiation energy of EB and the exposure amount of EUV are not particularly limited.

Post exposure bake (PEB) may be performed after irradiation with EB or EUV and before development.

The baking temperature is not particularly limited, but is preferably 60° C. to 150° C., more preferably 70° C. to 120° C., and particularly preferably 75° C. to 110° C.

The baking time is not particularly limited, but is preferably 1 second to 10 minutes, more preferably 10 seconds to 5 minutes, and particularly preferably 30 seconds to 3 minutes.

For the development, for example, an alkaline developer is used.

Examples of the development temperature include 5° C. to 50° C.

The developing time is, for example, 10 seconds to 300 seconds.

Examples of the alkaline developer include: alkali aqueous solution such as inorganic alkalis (for example, sodium hydroxide, potassium hydroxide, sodium carbonate, sodium silicate, sodium metasilicate, or aqueous ammonia); primary amines (for example, ethylamine and n-propylamine); secondary amines (for example, diethylamine and di-n-butylamine); tertiary amines (for example, triethylamine and methyldiethylamine); alcohol amines (for example, dimethylethanolamine and triethanolamine); quaternary ammonium salts (for example, tetramethylammonium hydroxide, tetraethylammonium hydroxide, and choline); and cyclic amines (for example, pyrrole and piperidine). Furthermore, it is also possible to add an appropriate amount of an alcohol, such as isopropyl alcohol, or a nonionic surfactant to the aqueous solution of an alkali. Among these, preferred developers are an aqueous solution of a quaternary ammonium salt, more preferably an aqueous solution of tetramethylammonium hydroxide and an aqueous solution of choline. Furthermore, a surfactant or the like can be added to these developers. In place of the alkaline developer, a method of performing development with an organic solvent such as butyl acetate and developing a part where the alkali dissolution rate of the photoresist is not improved can also be used.

Next, the resist underlayer film is etched using the formed resist pattern as a mask. The etching may be dry etching or wet etching, but is preferably dry etching.

When the inorganic film is formed on the surface of the used semiconductor substrate, the surface of the inorganic film is exposed, and when the inorganic film is not formed on the surface of the used semiconductor substrate, the surface of the semiconductor substrate is exposed. Thereafter, the semiconductor device can be manufactured through a step of processing the semiconductor substrate by a known method (dry etching method or the like).

### EXAMPLES

Next, the contents of the present invention will be specifically described with reference to Examples, but the present invention is not limited thereto.

The weight average molecular weight of the polymer shown in the following Synthesis Examples 1 to 2 of the present specification is a measurement result by gel permeation chromatography (hereinafter abbreviated as GPC). For the measurement, a GPC apparatus manufactured by Tosoh Corporation was used, and measurement conditions and the like are as follows.
GPC column: Asahipak [registered trademark] GF-310 HQ, GF-510 HQ, GF-710 HQ
Column temperature: 40° C.
Solvent: N,N-dimethylformamide (DMF)
Flow rate: 0.6 ml/min
Standard sample: polystyrene (manufactured by Tosoh Corporation)

The weight average molecular weight of the polymer shown in the following Comparative Synthesis Example 1 of the present specification is a measurement result by gel permeation chromatography (hereinafter abbreviated as GPC). For the measurement, a GPC apparatus manufactured by Tosoh Corporation was used, and measurement conditions and the like are as follows.
GPC column: TSKgel Super-Multipore HZ-N (two columns)
Column temperature: 40° C.
Solvent: Tetrahydrofuran (THF)
Flow rate: 0.35 ml/min
Standard sample: polystyrene (manufactured by Tosoh Corporation)

### Synthesis Example 1

5.00 g of N-(2-hydroxyethyl) acrylamide (manufactured by Tokyo Chemical Industry Co., Ltd.), 4.10 g of adamantane methacrylate (manufactured by Tokyo Chemical Industry Co., Ltd.), and 0.46 g of azobisisobutyronitrile (manufactured by Tokyo Chemical Industry Co., Ltd.) were dissolved in 22.30 g of propylene glycol monomethyl ether (hereinafter abbreviated as PGME in the present specification), then the resulting solution was added to 15.93 g of PGME heated and kept at 80° C., and the mixture was reacted for 24 hours to obtain a solution containing Polymer 1. As a result of GPC analysis, the obtained Polymer 1 had a weight average molecular weight of 36,200 and a dispersion degree of 4.0 in terms of standard polystyrene. The structure present in Polymer 1 is represented by the following formula.

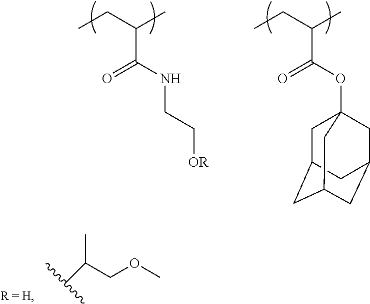

### Synthesis Example 2

7.00 g of N-(2-hydroxyethyl) acrylamide (manufactured by Tokyo Chemical Industry Co., Ltd.), 2.61 g of methyl methacrylate (manufactured by Tokyo Chemical Industry Co., Ltd.), and 1.20 g of azobisisobutyronitrile (manufactured by Tokyo Chemical Industry Co., Ltd.) were dissolved in 25.22 g of PGME, and then the resulting solution was added to 18.02 g of PGME heated and kept at 80° C., and the mixture was reacted for 24 hours to obtain a solution containing Polymer 2. As a result of GPC analysis, the obtained Polymer 2 had a weight average molecular weight of 16,200 and a dispersion degree of 3.6 in terms of standard polystyrene. The structure present in Polymer 2 is represented by the following formula.

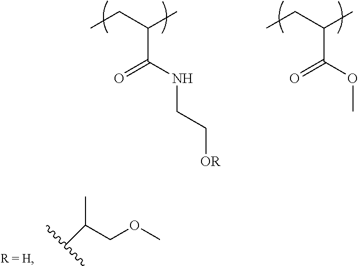

### Synthesis Example 3

9.53 g of N-phenylacrylamide (manufactured by Tokyo Chemical Industry Co., Ltd.), 4.00 g of 2-hydroxypropyl methacrylate (manufactured by FUJIFILM Wako Pure Chemical Corporation), and 0.61 g of azobisisobutyronitrile (manufactured by Tokyo Chemical Industry Co., Ltd.) were dissolved in 32.98 g of PGME, and then the resulting solution was added to 23.56 g of PGME heated and kept at 100° C., and the mixture was reacted for 16 hours to obtain a solution containing Polymer 3. As a result of GPC analysis, the obtained Polymer 3 had a weight average molecular weight of 10,400 and a dispersion degree of 2.3 in terms of standard polystyrene. The structure present in Polymer 3 is represented by the following formula.

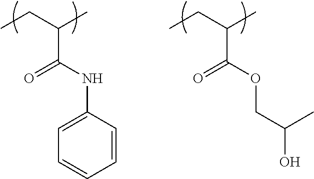

### Synthesis Example 4

8.23 g of N-phenylacrylamide (manufactured by Tokyo Chemical Industry Co., Ltd.), 4.00 g of 2-hydroxypropyl methacrylate (manufactured by FUJIFILM Wako Pure Chemical Corporation), and 0.61 g of azobisisobutyronitrile (manufactured by Tokyo Chemical Industry Co., Ltd.) were dissolved in 29.96 g of PGME, and then the resulting solution was added to 21.40 g of PGME heated and kept at 100° C., and the mixture was reacted for 16 hours to obtain a solution containing Polymer 4. As a result of GPC analysis, the obtained Polymer 4 had a weight average molecular weight of 10,500 and a dispersion degree of 2.2 in terms of standard polystyrene. The structure present in Polymer 4 is represented by the following formula.

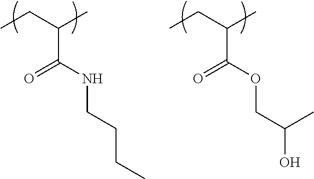

### Synthesis Example 5

3.27 g of N-(hydroxymethyl) acrylamide (manufactured by Tokyo Chemical Industry Co., Ltd.), 2.00 g of 2-hydroxypropyl methacrylate (manufactured by FUJIFILM Wako Pure Chemical Corporation), and 0.61 g of azobisisobutyronitrile (manufactured by Tokyo Chemical Industry Co., Ltd.) were dissolved in 13.54 g of N-methylpyrrolidone (hereinafter abbreviated as NMP in the present specification) in a reaction vessel, and then the resulting solution was added to 9.67 g of NMP heated and kept at 100° C., and stirred for 16 hours. After completion of the reaction, a polymer solution was added dropwise to 145 g of propylene glycol monomethyl ether acetate, and the white precipitate was filtered, dried, and then redissolved in propylene glycol monomethyl ether. As a result of GPC analysis with respect to the obtained polymer solution, the obtained Polymer 5 had a weight average molecular weight of 5,700 and a dispersion degree of 3.9 in terms of standard polystyrene. The structure present in Polymer 5 is represented by the following formula.

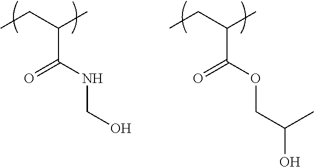

### Synthesis Example 6

5.05 g of N-(hydroxyethyl) acrylamide (manufactured by Tokyo Chemical Industry Co., Ltd.), 5.00 g of methyl methacrylate (manufactured by Tokyo Chemical Industry Co., Ltd.), and 0.66 g of azobisisobutyronitrile (manufactured by Tokyo Chemical Industry Co., Ltd.) were dissolved in 24.98 g of PGME, and then the resulting solution was added to 17.84 g of PGME heated and kept at 100° C., and the mixture was reacted for 16 hours to obtain a solution containing Polymer 6. As a result of GPC analysis, the obtained Polymer 6 had a weight average molecular weight of 8,300 and a dispersion degree of 2.5 in terms of standard polystyrene. The structure present in Polymer 6 is represented by the following formula.

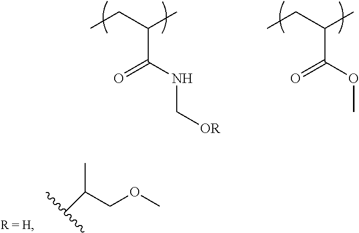

### Comparative Synthesis Example 1

100.00 g of monoallyl diglycidyl isocyanuric acid (manufactured by Shikoku Chemicals Corporation), 66.4 g of 5,5-diethylbarbituric acid (manufactured by TATEYAMA KASEI Co., Ltd.), and 4.1 g of benzyltriethylammonium chloride were added to 682.00 g of propylene glycol monomethyl ether in a reaction vessel, and dissolved. The reaction vessel was purged with nitrogen, and then reacted at 130° C. for 24 hours to obtain a solution containing Comparative Polymer 1. As a result of GPC analysis, the obtained Comparative Polymer 1 had a weight average molecular weight of 6,800 and a dispersion degree of 4.8 in terms of standard polystyrene. The structure present in Comparative Polymer 1 is represented by the following formula.

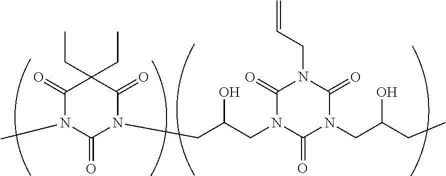

### (Preparation of Resist Underlayer Film)

### Examples and Comparative Examples

The polymer, the crosslinking agent, the curing catalyst, and the solvent obtained in Synthesis Example 1 to 6 and Comparative Synthesis Example 1 were mixed in the proportions shown in Table 1, and the mixture was filtered through a fluororesin filter having a pore size of 0.1 μm, thereby preparing the composition for forming a resist underlayer film for EB or EUV lithography of Examples 1 to 7 and the composition for forming a resist underlayer film of Comparative Example 1, respectively.

Abbreviations in Table 1 are as follows.
PL-LI: Tetramethoxymethyl glycoluril
PGME-PL: Imidazo[4,5-d]imidazole-2,5 (1H, 3H)-dione, tetrahydro-1,3,4,6-tetrakis[(2-methoxy-1-methylethoxy)methyl]-(the following structural formula)

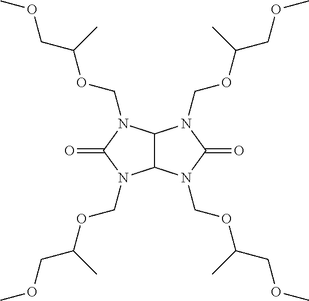

PyPSA: Pyridinium-p-hydroxybenzenesulfonic acid
R-30N: Surfactant (product name: R-40, manufactured by DIC Corporation)
PGMEA: Propylene glycol monomethyl ether acetate
PGME: Propylene glycol monomethyl ether

TABLE 1

| | | Crosslinking | Curing | | | |
|---|---|---|---|---|---|---|
| | Polymer | agent | catalyst | Surfactant | Solvent | |
| Example 1 | Polymer 1 | — | PyPSA | — | PGME | PGMEA |
| (parts by | 0.176 | — | 0.004 | — | 90 | 10 |
| mass) | | | | | | |
| Example 2 | Polymer 2 | — | PyPSA | — | PGME | PGMEA |
| (parts by | 0.176 | — | 0.004 | — | 90 | 10 |
| mass) | | | | | | |
| Example 3 | Polymer 2 | PGME-PL | PyPSA | — | PGME | PGMEA |
| (parts by | 0.134 | 0.037 | 0.003 | — | 90 | 10 |
| mass) | | | | | | |
| Example 4 | Polymer 3 | PGME-PL | PyPSA | — | PGME | PGMEA |
| (parts by | 0.134 | 0.037 | 0.003 | — | 90 | 10 |
| mass) | | | | | | |
| Example 5 | Polymer 4 | PGME-PL | PyPSA | — | PGME | PGMEA |
| (parts by | 0.134 | 0.037 | 0.003 | — | 90 | 10 |
| mass) | | | | | | |
| Example 6 | Polymer 5 | PGME-PL | PyPSA | — | PGME | PGMEA |
| (parts by | 0.134 | 0.037 | 0.003 | — | 90 | 10 |
| mass) | | | | | | |
| Example 7 | Polymer 6 | PGME-PL | PyPSA | — | PGME | PGMEA |
| (parts by | 0.134 | 0.037 | 0.003 | — | 90 | 10 |
| mass) | | | | | | |
| Comparative | Comparative | PL-LI | PyPSA | R-30N | PGME | PGMEA |
| Example 1 | Polymer 1 | | | | | |
| (parts by | 0.149 | 0.037 | 0.003 | 0.001 | 70 | 30 |
| mass) | | | | | | |

### (Elution Test in Photoresist Solvent)

Each of the compositions for forming a resist underlayer film for EB or EUV lithography of Examples 1 to 7 and the composition for forming a resist underlayer film of Comparative Example 1 was applied onto a silicon wafer using a spinner. The silicon wafer was baked on a hot plate at 205° C. for 60 seconds to obtain a film having a film thickness of 5 nm. These resist underlayer films were immersed in a mixed solution of propylene glycol monomethyl ether/propylene glycol monomethyl ether acetate=70/30 (volume ratio), which is a solvent used for the photoresist, and when the film thickness change was less than 5 Å, the resist underlayer films were evaluated as good, and when the thickness change was 5 Å or more, the resist underlayer films were evaluated as poor, and the results are shown in Table 2.

TABLE 2

| | Elution test |
|---|---|
| Example 1 | Good |
| Example 2 | Good |
| Example 3 | Good |
| Example 4 | Good |
| Example 5 | Good |
| Example 6 | Good |
| Example 7 | Good |
| Comparative | Good |
| Example 1 | |

### (Evaluation of Resist Patterning)

### [Test for Forming Resist Pattern by Electron Beam Drawing Apparatus]

Compositions for forming a resist underlayer film were each applied onto a silicon wafer using a spinner. The silicon wafer was baked on a hot plate at 205° C. for 60 seconds to obtain a resist underlayer film having a film thickness of 5 nm. An EUV positive resist solution was spin-coated on the resist underlayer film, and heated at 130° C. for 60 seconds to form an EUV resist film. The resist film was irradiated with EB under predetermined conditions using an electron beam drawing apparatus (ELS-G130). After the irradiation, baking (PEB) was performed at 90° C. for 60 seconds, cooling was performed on a cooling plate to room temperature, and paddle development was performed for 30 seconds using a 2.38% aqueous tetramethylammonium hydroxide solution (product name NMD-3 manufactured by TOKYO OHKA KOGYO CO., LTD.) as a photoresist developer. A resist pattern having a line size of 16 nm to 28 nm was formed. A scanning electron microscope (CG4100 manufactured by Hitachi High-Technologies Corporation) was used for measuring the length of the resist pattern.

For the photoresist pattern obtained in this manner, whether or not a 22 nm line-and-space (L/S) could be formed was evaluated. In Examples 1 to 7, 22 nmL/S pattern formation was confirmed. In addition, the amount of charge forming the 22 nm line/44 nm pitch (line-and-space (L/S=1/1)) is defined as the optimal irradiation energy, and the irradiation energy (μC/cm²) and the LWR at that time are shown in Table 3. In Examples 1 to 7, it was confirmed that the LWR was improved as compared with Comparative Example 1, and in Example 1 and Examples 3 to 7, it was confirmed that the minimum CD size was improved as compared with Comparative Example 1.

The minimum CD size indicates a limit CD size at which no pattern collapse occurred, and the LWR indicates a value in the 22 nm L/S pattern.

TABLE 3

| | Irradiation | Minimum | |
|---|---|---|---|
| | energy | CD size | LWR |
| | (uC/cm²) | (nm) | (nm) |
| Example 1 | 480 | 17.2 | 3.36 |
| Example 2 | 485 | 22.2 | 3.50 |
| Example 3 | 517 | 18.4 | 3.13 |
| Example 4 | 476 | 18.3 | 3.31 |
| Example 5 | 497 | 17.5 | 3.25 |
| Example 6 | 524 | 17.9 | 3.37 |
| Example 7 | 507 | 18.0 | 3.48 |
| Comparative | 496 | 20.4 | 3.51 |
| Example 1 | | | |

1. A composition for forming a resist underlayer film for EB or EUV lithography, the composition including:
a polymer; and
a solvent;
wherein the polymer contains a repeating unit represented by the following Formula (1). 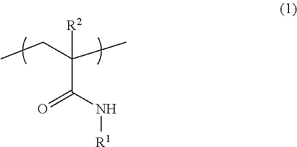
(In Formula (1), R¹ represents a monovalent organic group having 1 to 20 carbon atoms, and R² represents a hydrogen atom or an alkyl group having 1 to 6 carbon atoms.)

2. The composition for forming a resist underlayer film for EB or EUV lithography according to claim 1, wherein R¹ in the Formula (1) represents the following Formula (1X). 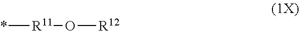
(In Formula (1X), R¹¹ represents an alkylene group having 1 to 4 carbon atoms, and R¹² represents a hydrogen atom, an alkyl group having 1 to 6 carbon atoms, or an alkoxyalkyl group having 2 to 10 carbon atoms in total. * represents an atomic bonding.)

3. The composition for forming a resist underlayer film for EB or EUV lithography according to claim 2, wherein, in the Formula (1X), R¹¹ represents a methylene group or a 1,2-ethylene group.

4. The composition for forming a resist underlayer film for EB or EUV lithography according to claim 2, wherein, in the Formula (1X), R¹² represents a hydrogen atom or an alkoxyalkyl group having 2 to 6 carbon atoms in total.

5. The composition for forming a resist underlayer film for EB or EUV lithography according to claim 1, wherein the polymer further contains a repeating unit represented by the following Formula (2). 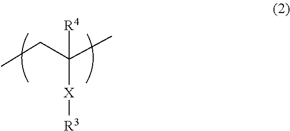
(In Formula (2), X represents a single bond or —COO—, R³ represents a monovalent organic group having 1 to 20 carbon atoms, and R⁴ represents a hydrogen atom or an alkyl group having 1 to 6 carbon atoms.)

6. The composition for forming a resist underlayer film for EB or EUV lithography according to claim 5, wherein X in the Formula (2) represents —COO—, and R³ represents a linear or branched alkyl group having 1 to 20 carbon atoms, a monovalent group having 2 to 20 carbon atoms in total and having a cyclic structure optionally having a heteroatom, or the following Formula (2X). 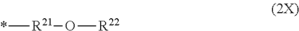
(In Formula (2X), R²¹ represents an alkylene group having 1 to 4 carbon atoms, and R²² represents a hydrogen atom, an alkyl group having 1 to 6 carbon atoms, or an alkoxyalkyl group having 2 to 10 carbon atoms in total. * represents an atomic bonding.)

7. The composition for forming a resist underlayer film for EB or EUV lithography according to claim 6, wherein
the linear or branched alkyl group having 1 to 20 carbon atoms is a linear or branched alkyl group having 1 to 6 carbon atoms,
the monovalent group having 2 to 20 carbon atoms in total and having a cyclic structure optionally having a heteroatom is a monovalent group obtained by removing one hydrogen atom from a monocyclic or polycyclic aliphatic ring having 3 to 10 carbon atoms, and
in the Formula (2X), R²¹ represents a methylene group, a 1,2-ethylene group, or a propylene group.

8. The composition for forming a resist underlayer film for EB or EUV lithography according to claim 6, wherein
the linear or branched alkyl group having 1 to 20 carbon atoms is a linear or branched alkyl group having 1 to 6 carbon atoms,
the monovalent group having 2 to 20 carbon atoms in total and having a cyclic structure optionally having a heteroatom is a monovalent group obtained by removing one hydrogen atom from a monocyclic or polycyclic aliphatic ring having 3 to 10 carbon atoms, and
in the Formula (2X), R²² represents a hydrogen atom or an alkoxyalkyl group having 2 to 6 carbon atoms in total.

9. The composition for forming a resist underlayer film for EB or EUV lithography according to claim 5, wherein a molar ratio between the repeating unit represented by the Formula (1) and the repeating unit represented by the Formula (2) in the polymer (Formula (1):Formula (2)) is 30:70 to 90:10.

10. The composition for forming a resist underlayer film for EB or EUV lithography according to claim 1, further containing a crosslinking agent.

11. The composition for forming a resist underlayer film for EB or EUV lithography according to claim 1, further containing a curing catalyst.

12. The composition for forming a resist underlayer film for EB or EUV lithography according to claim 1, wherein the composition is used for forming a resist underlayer film for EB or EUV lithography having a film thickness of 10 nm or less.

13. A resist underlayer film for EB or EUV lithography which is a cured product of the composition for forming a resist underlayer film for EB or EUV lithography according to claim 1.

14. A substrate for semiconductor processing comprising:
a semiconductor substrate; and
the resist underlayer film for EB or EUV lithography according to claim 13.

15. A method for manufacturing a semiconductor element,
the method comprising:
a step of forming a resist underlayer film on a semiconductor substrate using the composition for forming a resist underlayer film for EB or EUV lithography according to claim 1; and
a step of forming a resist film on the resist underlayer film using a resist for EB or EUV lithography.

16. A pattern forming method comprising:
a step of forming a resist underlayer film on a semiconductor substrate using the composition for forming a resist underlayer film for EB or EUV lithography according to claim 1;
a step of forming a resist film on the resist underlayer film using a resist for EB or EUV lithography;
a step of irradiating the resist film with EB or EUV, and then developing the resist film to obtain a resist pattern; and
a step of etching the resist underlayer film using the resist pattern as a mask.

17. A method for improving LWR of a resist pattern, the method comprising:
a step of forming a resist underlayer film on a semiconductor substrate using the composition for forming a resist underlayer film for EB or EUV lithography according to claim 1;
a step of forming a resist film on the resist underlayer film using a resist for EB or EUV lithography; and
a step of irradiating the resist film with EB or EUV, and then developing the resist film to obtain a resist pattern.
